(19) United States
(12) Patent Application Publication
(10) Pub. No.: US 2014/0209174 A1
(43) Pub. Date: Jul. 31, 2014

(54) INK FOR FORMING COMPOUND SEMICONDUCTOR THIN FILM AND PRODUCTION METHOD THEREOF

(71) Applicants: TOPPAN PRINTING CO.,LTD., Tokyo (JP); TOKYO INSTITUTE OF TECHNOLOGY, Tokyo (JP)

(72) Inventors: Yiwen ZHANG, Tokyo (JP); Akira YAMADA, Tokyo (JP)

(73) Assignees: TOKYO INSTITUTE OF TECHNOLOGY, Tokyo (JP); TOPPAN PRINTING CO.,LTD., Tokyo (JP)

(21) Appl. No.: 14/229,133

(22) Filed: Mar. 28, 2014

Related U.S. Application Data
(63) Continuation of application No. PCT/JP2012/074461, filed on Sep. 25, 2012.

(30) Foreign Application Priority Data
Sep. 30, 2011 (JP) 2011-217028
Feb. 27, 2012 (JP) 2012-040060

(51) Int. Cl. H01L 31/032; H01L 31/18

(52) U.S. Cl. CPC H01L 31/0326; H01L 31/18
USPC 136/264; 136/265; 438/95; 252/519.14

(57) ABSTRACT

A method for producing a nanoparticle for forming a CZTS compound semiconductor thin film is provided which includes the step of reacting a solution including a metal salt or a metal complex with a solution including a chalcogenide salt to produce a CZTS compound nanoparticle. A CZTS compound semiconductor thin film is formed by coating or printing the nanoparticle for forming the CZTS compound semiconductor thin film, and subjecting it to a heat treatment. A solar cell including the CZTS compound semiconductor thin film as the light-absorbing layer is provided.

### CROSS REFERENCE TO RELATED APPLICATIONS

This is a Continuation Application of PCT Application No. PCT/JP2012/074461, filed Sep. 25, 2012, which was published under PCT Article 21(2) in Japanese. This application is based upon and claims the benefit of priority from prior Japanese Patent Applications No. 2011-217028, filed Sep. 30, 2011 and No. 2012-040060, filed Feb. 27, 2012, the entire contents of both of which are incorporated herein by reference.

### BACKGROUND OF THE INVENTION

1. Field of the Invention

The present invention relates to a method for producing a nanoparticle, an ink for forming a compound semiconductor thin film including the nanoparticle and a production method thereof, a compound semiconductor thin film formed using the ink, a solar cell comprising the compound semiconductor thin film, and a method for producing the solar cell.

2. Description of the Related Art

A solar cell is a device which converts light energy into electrical energy using a photovoltaic effect and has recently attracted attention from the viewpoints of global warming prevention and as a substitute for depleting resources. As a semiconductor used in the solar cell, monocrystal Si, polycrystal Si, amorphous Si, CdTe, CuIn₁₋ₓGaₓSe₂ (CIGS), Cu₂ZnSn(S,Se)₄ (CZTS), GaAs, InP, and the like are known. Of these, Cu₂ZnSn(S,Se)₄ (CZTS) is characterized by having a high optical absorption coefficient, a band-gap energy (1.4 to 1.5 eV) suitable for the solar cell, low environmental burden, and including no rare elements. It is expected to be used for future solar cells used as a substitute product of a CIS (CuInSe₂) thin film solar cell or a CdTe thin film solar cell, which is now commercialized.

Various methods for producing a CZTS compound semiconductor have hitherto been proposed. For example, JP-A 2009-26891 (KOKAI) proposes a method for producing a CZTS thin film including producing a CZTS precursor from Cu, ZnS and SnS as starting materials on a Mo-coated SLG substrate using a sputtering method, and heating the resulting film at 580° C. for 2 hours in a 20% hydrogen sulfide atmosphere.

According to the method, however, sulfur is selectively evaporated during the sputtering due to the influence of plasma, because of a low melting temperature of sulfur or SnS, thus resulting in the difficulty of obtaining a CZTS thin film having a desired composition ratio. In addition, using a vacuum process such as sputtering leads to a high capital investment, a high electric power consumption, and a relatively high cost.

In order to improve the problems described above, US 2011/0097496 proposes a method in which Cu₂S, Zn, SnSe, S and Se are dissolved in a hydrazine solvent, and the solution is subjected to thermal annealing to produce a CZTS compound semiconductor. According to this method, a phenomenon in which sulfur is selectively evaporated during the sputtering does not occur, and the capital investment can be reduced and the low cost can be realized, because of the use of a non-vacuum process.

According to this method, however, special attention is needed for handling, because hydrazine, which is a toxic and highly explosive solvent, is used, and thus the method has a problem of high environmental burden. For that reason, it is difficult to use this method in mass production on an industrial scale.

### BRIEF SUMMARY OF THE INVENTION

The present invention has been made under the circumstances described above, and the object of the invention is to provide a method for producing nanoparticles for forming a CZTS compound semiconductor thin film, capable of producing a low cost solar cell, an ink for forming a compound semiconductor thin film including the nanoparticles and a production method thereof, a compound semiconductor thin film formed using the ink, a solar cell comprising the CZTS compound semiconductor thin film, and a method for producing the solar cell.

In order to solve the problems described above, a first aspect of the present invention provides a method for producing a nanoparticle for forming a CZTS compound semiconductor thin film including the step of reacting a solution including a metal salt or a metal complex with a solution including a chalcogenide salt to produce a CZTS compound nanoparticle.

In the method for producing such a nanoparticle for forming a CZTS compound semiconductor thin film, the temperature at which the nanoparticles are produced can be controlled to a temperature of −67° C. or higher and 25° C. or lower, and more preferably, the temperature can be controlled to −5° C. or higher and 5° C. or lower.

As the metal salt, a salt including a halogen atom can be used.

As the metal salt, a metal iodide salt can be used.

As the metal iodide salt, at least one selected from the group consisting of CuI, ZnI₂, SnI₄, SnCl₄, and SnBr₄ can be used.

As the chalcogenide salt, at least one selected from the group consisting of Na₂Se and Na₂S can be used.

The nanoparticle can be a nanoparticle including a compound represented by Cu₂₋ₓZn_{1+y}SnS_{z}Se_{4-z} (0≦x≦1, 0≦y≦1, 0≦z≦4).

The nanoparticle described above can be at least one selected from the group consisting of a compound represented by Cu₂₋ₓS_{y}Se_{2-y} (0≦x≦1, 0≦y≦2), a compound represented by Zn₂₋ₓS_{y}Se_{2-y} (0≦x≦1, 0≦y≦2), and a compound represented by Sn₂₋ₓS_{y}Se_{2-y} (0≦x≦1, 0≦y≦2).

As the nanoparticle, a nanoparticle having a particle diameter of 1 to 200 nm can be used.

As the nanoparticle, a nanoparticle having a composition ratio Cu/(Zn+Sn) of elements forming the compound of 0.6 to 0.99 can be used.

A second aspect of the present invention provides a nanoparticle for forming a CZTS compound semiconductor thin film which is produced in accordance with the method described above.

A third aspect of the present invention provides an ink for forming a CZTS compound semiconductor thin film including the nanoparticle according to the second aspect of the present invention dispersed in an organic solvent.

A fourth aspect of the present invention provides a method for producing an ink for forming a CZTS compound semiconductor thin film including the step of dispersing the nanoparticle according to the second aspect of the present invention in an organic solvent.

As the organic solvent, at least one selected from the group consisting of methanol and pyridine can be used.

At least one selected from the group consisting of a Se compound and a S compound can be added to the ink as a binder.

Thiourea can be added to the ink as a binder.

A particle of at least one selected from the group consisting of a particle including a Se element and a particle including a S element can be added to the ink as a binder.

A particle of at least one selected from the group consisting of a Se particle and a S particle can be added to the ink as a binder.

As the nanoparticle added to the ink, a particle having a particle diameter of 1 to 200 nm can be used.

A fifth aspect of the present invention provides a CZTS compound semiconductor thin film formed by coating or printing the ink for forming a CZTS compound semiconductor thin film according to the third aspect of the present invention, and subjecting it to a heat treatment.

A sixth aspect of the present invention provides a solar cell including a light-absorbing layer, which includes a CZTS compound semiconductor thin film formed by coating or printing the ink for forming a CZTS compound semiconductor thin film according to the third aspect of the present invention on an electrode formed on a substrate and subjecting it to a heat treatment.

A seventh aspect of the present invention provides a method for producing a solar cell including the steps of coating or printing the ink for forming a CZTS compound semiconductor thin film according to the third aspect of the present invention on an electrode formed on a substrate to form a coating film of the CZTS compound semiconductor, and subjecting the coating film of the CZTS compound semiconductor to a heat treatment to form a light-absorbing layer including the CZTS compound semiconductor thin film.

The heat treatment temperature of the coating film of the CZTS compound semiconductor can be controlled at 460° C. to 650° C.

### BRIEF DESCRIPTION OF THE SEVERAL VIEWS OF THE DRAWING

FIG. 1 is a vertical cross-sectional side view schematically showing a solar cell according to an embodiment of the present invention.

FIG. 2 is a characteristic diagram showing in-situ XRD measurement results, used for obtaining heat treatment temperatures of a coating film of an ink for forming a semiconductor thin film according to an embodiment of the present invention.

### DETAILED DESCRIPTION OF THE INVENTION

Embodiments of the present invention are explained below, referring to figures.

The CZTS compound used in the instant specification refers to a compound semiconductor having a basic structure of Cu₂ZnSn(S,Se)₄ wherein In in a compound CuInSe (CIS) is substituted by Zn or Sn, and Se is substituted by S.

First, the first embodiment of the present invention is explained.

The method for producing nanoparticles according to the first embodiment of the present invention is characterized by reacting a solution including a metal salt or a metal complex with a solution including a chalcogenide salt to produce a nanoparticle for forming a CZTS compound semiconductor thin film.

As the metal salt or the metal complex, CuI, CuSO₄, Cu(NO₃)₂, Cu(CH₃COO)₂, ZnI₂, ZnSO₄, Zn(NO₃)₂, Zn(CH₃COO)₂, SnI₂, SnSO₄, Sn(CH₃COO)₂, and the like, can be used.

As the metal salt, a salt including a halogen atom is preferable. The metal salt including the halogen atom may include, for example, CuCl₂, CuBr, CuI, ZnCl₂, ZnBr₂, ZnI₂, SnCl₂, SnBr₂, SnI, SnI₄, SnCl₄, SnBr₄ and the like. At least one selected from the group consisting of CuI, ZnI₂ and SnI₂ is particularly preferable.

As the chalcogenide salt, K₂Se, Na₂Se, K₂S, Na₂S, and the like can be used. A mixture thereof can also be used.

When Na₂Se or Na₂S is used as the chalcogenide salt, NaI, which is a by-product generated by a reaction thereof with a metal iodide, can be, preferably, easily separated from the nanoparticles by centrifugation, or the like, because of their high solubility in an organic solvent.

It is desirable to produce the nanoparticles at a temperature of −67° C. or higher and 25° C. or lower. When the temperature is higher than 25° C., the reaction rate becomes too high, and it tends to be difficult to control the particle diameter. When the temperature is lower than −67° C., the reaction rate is too slow, and the production time tends to be prolonged. More preferably temperatures are −5° C. or higher and 5° C. or lower.

The nanoparticle, which is the reaction product of the solution including the metal salt or metal complex with the solution including the chalcogenide salt, can be, for example, a particle of a compound represented by Cu₂₋ₓZn_{1+y}SnS_{z}Se_{4-z} (0≦x≦1, 0≦y≦1, 0≦z≦4).

The nanoparticles can also be a mixture of at least one selected from the group consisting of particles of a compound represented by Cu₂₋ₓS_{y}Se_{2-y} (0≦x≦1, 0≦y≦2), a compound represented by Zn₂₋ₓS_{y}Se_{2-y} (0≦x≦1, 0≦y≦2), and a compound represented by Sn₂₋ₓS_{y}Se_{2-y} (0≦x≦1, 0≦y≦2). A compound including Cu (IB group), Zn (IIB group), Sn (IVB group), S (VIB group) and/or Se (VIB group) is generally referred to as a CZTS compound.

The nanoparticles produced in accordance with the method of the present invention have preferably an average particle diameter of 1 nm or more and 200 nm or less. When the nanoparticles have an average particle diameter of more than 200 nm, gaps are easily formed in the CZTS compound semiconductor thin film during the step in which the CZTS compound semiconductor thin film is subjected to the heat treatment, the surface roughness becomes high, and it tends to reduce a photoelectric conversion efficiency.

On the other hand, when the nanoparticles have an average particle diameter of less than 1 nm, the particles are easily aggregated, and thus it is difficult to prepare an ink. The nanoparticles have more preferably an average particle diameter of 5 nm or more and 100 nm or less. The average particle diameter of the nanoparticles is an average value of the shortest diameters of metal nanoparticles observed using an SEM (scanning electron microscope) or TEM (transmission electron microscope).

A composition ratio of the embodiments of the compound or the mixture forming the nanoparticle, Cu/(Zn+Sn), is preferably from 0.6 to 0.99, more preferably from 0.8 to 0.9. When the ratio Cu/(Zn+Sn) is 1 or more, it is easy to generate a semimetal, CuS, and the resulting CZTS thin film has too low a resistance, thus resulting in a possibility of reduced photoelectric conversion efficiency. When the ratio Cu/(Zn+Sn) is less than 0.6, the semiconductor has a low carrier concentration, and the photoelectric conversion efficiency may possibly be reduced.

The nanoparticles, which are obtained in accordance with the present embodiment as explained above, are dispersed in an organic solvent, whereby the ink for forming the CZTS compound semiconductor thin film can be produced.

The organic solvent is not particularly limited, and, for example, alcohols, ethers, esters, aliphatic hydrocarbons, alicyclic hydrocarbons, aromatic hydrocarbons and the like can be used. Preferable organic solvents may include alcohols having less than 10 carbon atoms such as methanol, ethanol and butanol, diethyl ether, pentane, hexane, cyclohexane and toluene, and particularly preferable organic solvents may include methanol, pyridine, toluene and hexane.

In order to efficiently disperse the nanoparticles in the organic solvent, a dispersant can be added to the ink for forming the CZTS compound semiconductor thin film. The dispersant may include thiols, selenols, alcohols having 10 or more carbon atoms, and the like.

In order to obtain a dense semiconductor thin film, it is also possible to add a binder to the ink for forming the CZTS compound semiconductor thin film. As the binder, Se particles, S particles, a Se compound, a S compound, and the like can be used. Thiourea may also be added thereto as the binder. A solid concentration in the organic solvent is not particularly limited, and it is generally from 1 to 20% by weight.

The particles added as the binder can have a particle diameter of 1 to 200 nm. It is preferable that the particle diameter of the particles added as the binder is smaller than the particle diameter of the nanoparticles.

Next, an explanation is made for a CZTS compound semiconductor thin film according to the second embodiment of the present invention.

The CZTS compound semiconductor thin film according to the second embodiment of the present invention is formed by coating or printing the ink for forming the CZTS compound semiconductor thin film described above on a substrate, drying it to remove the organic solvent therefrom, and subjecting the resulting film to a heat treatment.

The coating method may include a doctor method, a spin coating method, a slit coating method, a spray method, and the like. The printing method may include a gravure printing method, a screen printing method, a reverse offset printing method, a relief printing method, and the like.

The coating film formed by the coating or printing has preferably such a thickness is that a thickness of the CZTS compound semiconductor thin film is from 0.5 to 10 μm such as about 2 μm after the drying or the heat treatment. The heat treatment can be performed by annealing in a heating furnace or rapid thermal annealing (RTA).

The heat treatment temperature is desirably 350° C. or higher, because the temperature is required to be a temperature necessary for the crystallization of the CZTS compound semiconductor. When a glass substrate is used as the substrate, the heat treatment temperature is desirably 650° C. or lower, particularly 550° C. or lower, because it is necessary that the glass substrate can withstand that temperature. The range thereof is preferably from 450° C. to 650° C., more preferably from 450° C. to 550° C.

According to experiments performed by the present inventors, it is confirmed that the crystallization of the CZTS compound semiconductor is rapidly advanced at the heat treatment temperature of 460 to 500° C. The heat treatment temperature of the coating film of the ink for forming the CZTS compound semiconductor thin film is, accordingly, most preferably from 460 to 500° C.

The heat treatment can be performed in at least one atmosphere selected from the group consisting of a nitrogen atmosphere, an argon atmosphere, a forming gas atmosphere, a hydrogen atmosphere, a Se gas atmosphere, a S gas atmosphere, an H₂Se gas atmosphere, and an H₂S gas atmosphere. When the treatment is performed in an atmosphere of both Se gas and S gas, a band structure can be controlled. In order to form a grade band, preferably the film is first treated in an atmosphere including the Se element, and then an atmosphere including the S element.

The experiments performed by the present inventors and the results thereof are shown below.

An ink including Cu—Zn—Sn—Se—S nanoparticles is coated on a Pt plate as a substrate, the heat treatment is performed varying the heat treatment temperature within a range of 400° C. to 600° C., and the analysis thereof is performed using an in-situ XRD. The Cu—Zn—Sn—Se—S coating film used has a composition ratio described below.

Cu/(Zn+Sn)=0.74

Zn/Sn=1.3

Cu/Sn=1.7

Measurement conditions in the in-situ XRD are as follows:

Measurement Atmosphere: Nitrogen Atmosphere

Measurement Range: 25 to 35 deg

Rate of Temperature Rise: 10° C./minute

Scanning Speed: 10 deg/minute

The XRD scanning is started 2 minutes after the temperature reaches a predetermined temperature.

The measurement results are shown in FIG. 2.

From FIG. 2, it can be seen that the crystallization of the CZTS compound is rapidly advanced within a narrow temperature range of 460 to 500° C.

A solar cell according to the third embodiment of the present invention is explained below.

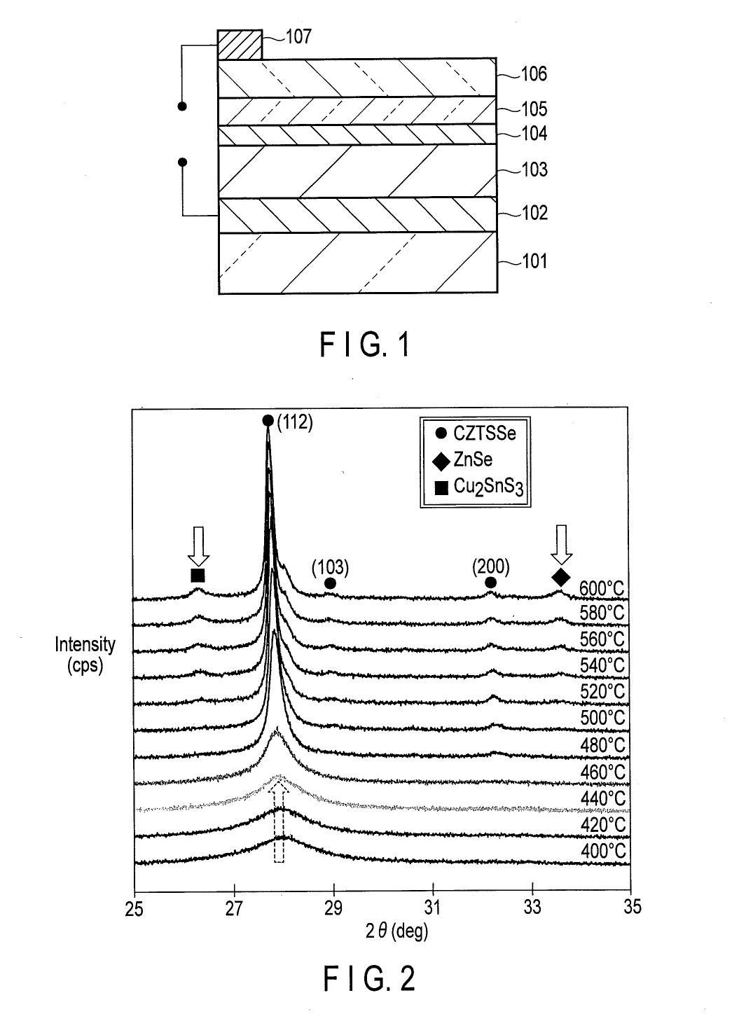

FIG. 1 is a vertical cross-sectional side view showing schematically the solar cell according to the third embodiment of the present invention. In the solar cell shown in FIG. 1, a back electrode 102 is formed on a substrate 101. As the substrate 101, a soda lime glass, a metal plate, a plastic film, and the like can be used.

As the back electrode 102, a metal such as molybdenum (Mo), nickel (Ni) or copper (Cu) can be used. A known carbon electrode such as carbon and graphene can also be used. Further, a known transparent conductive film such as ITO or ZnO can also be used.

The CZTS compound semiconductor thin film, according to the second embodiment, is formed on the back electrode 102, as a light-absorbing layer 103. The light-absorbing layer 103 is, accordingly, formed by coating the ink for forming the CZTS compound semiconductor thin film on the back electrode 102, drying it, and subjecting the resulting film to a heat treatment. This light-absorbing layer performs photoelectric conversion.

A buffer layer 104, an i-layer 105, and an n-layer 106 are sequentially formed on the light-absorbing layer 103. For the buffer layer 104, known CdS, Zn(S, O, OH) and In₂S₃ can be used. For the i-layer 105, a known metal oxide such as ZnO can be used. For the p-layer 106, known ZnO to which Al, Ga or B is added can be used.

Subsequently, a surface electrode 107 is formed on the n-layer 106, thereby completing a solar cell. As the surface electrode 107, a known metal such as Al or Ag can be used. A known carbon electrode such as carbon or graphene can also be used. Further a known transparent conductive film such as ITO or ZnO can also be used.

Although it is not illustrated, an antireflection film, which serves to suppress light reflection and allows much more light to be absorbed by the light-absorbing layer, can also be formed on the n-layer 106. A material for the antireflection film is not particularly limited, and for example, magnesium fluoride (MgF₂) can be used. The antireflection film has an appropriate thickness of about 100 nm.

In the solar cell having such a structure, according to the third embodiment, the ink for forming the CZTS compound semiconductor thin film in which the nanoparticles are dispersed is coated or printed, then dried, and the resulting film is subjected to a heat treatment, thereby forming the light-absorbing layer, and accordingly the area thereof can be easily made larger compared to the case in which the method shown in JP-A 2009-26891 (KOKAI) is employed, and it is possible to reduce the cost. In addition, compared to the method shown in US 2011/0097496, in which hydrazine is used as the solvent, the environmental burden can be further reduced, and the mass production in an industrial scale can be more easily realized.

### EXAMPLES

The present invention is explained in more detailed below based on Examples, but the invention is not limited thereto.

### Example 1

### (Production of Cu—Zn—Sn—Se—S Nanoparticles)

A solution in which CuI, ZnI₂, and SnI₂ were dissolved in pyridine was mixed with a solution in which Na₂Se and Na₂S were dissolved in methanol so that a ratio of Cu/Zn/Sn/Se/S was set to 2.5/1.5/1.25/2/2. This mixture was reacted at 0° C. in an inert gas atmosphere to produce Cu—Zn—Sn—Se—S nanoparticles. As a result of observation using scanning microscopy, the obtained Cu—Zn—Sn—Se—S nanoparticles had an average particle diameter of 80 nm. The reaction solution was filtered, washed with methanol, and the obtained Cu—Zn—Sn—Se—S nanoparticles were dispersed in a mixed liquid of pyridine and methanol.

### (Preparation of Ink)

To the thus obtained dispersion of the Cu—Zn—Sn—Se—S nanoparticles was added thiourea as a binder so that a weight ratio of the Cu—Zn—Sn—Se—S nanoparticles to thiourea was set to 3:2. Methanol was added thereto so that the resulting mixture had a solid content of 5% by weight to prepare an ink.

Next, a solar cell having the structure shown in FIG. 1 was produced as follows:

### (Formation of Back Electrode 102)

A back electrode 102 made of an Mo layer was formed on a soda lime glass plate 101 using a sputtering method.

### (Formation of Light-Absorbing Layer 103)

The back electrode 102 was coated with the ink for forming the CZTS compound semiconductor thin film obtained as above in accordance with a doctor method, a solvent was evaporated therefrom in an oven having a temperature of 250° C., and then the resulting film was heated at 500° C. for 30 minutes to form a light-absorbing layer 103 of CZTSSe having a thickness of 2 μm.

### (Formation of Buffer Layer 104)

The structure in which the light-absorbing layer 103 was formed was immersed in a mixed aqueous solution including cadmium sulfate (CdSO₄), thiourea (NH₂CSNH₂) and aqueous ammonia (NH₄OH) in molar concentrations of 0.0015 M, 0.0075 M and 1.5 M, respectively, having a temperature of 70° C., thereby forming a buffer layer 104 made of CdS having a thickness of 50 nm on the light-absorbing layer 103.

(Formation of i-Layer 105)

An i-layer 105 made of ZnO having a thickness of 50 nm was formed on the buffer layer 104 from diethyl zinc and water as starting materials using an MOCVD method.

(Formation of n-Layer 106)

An n-layer 106 made of ZnO:B having a thickness of 1 μm was formed on the i-layer 105 from diethyl zinc, water and diborane as starting materials using an MOCVD method.

### (Formation of Surface Electrode 107)

A surface electrode 107 made of Al having a thickness of 0.3 μm was formed on the n-layer 106 using a vapor deposition method.

As described above, a CZTS solar cell was completed.

### Example 2

### (Production of Cu—Zn—Sn—Se Nanoparticles)

A solution in which CuI, ZnI₂ and SnI₂ were dissolved in pyridine was mixed with a solution in which Na₂Se was dissolved in methanol so that a ratio of Cu/Zn/Sn/Se was set to 2/1.5/1.2/3.7. This mixture was reacted at 0° C. in an inert gas atmosphere to produce Cu—Zn—Sn—Se nanoparticles. As a result of observation using scanning microscopy, the obtained Cu—Zn—Sn—Se nanoparticles had an average particle diameter of 50 nm. The reaction solution was filtered, washed with methanol, and the obtained Cu—Zn—Sn—Se nanoparticles were dispersed in a mixed liquid of pyridine and methanol.

### (Preparation of Ink)

To the thus obtained dispersion of the Cu—Zn—Sn—Se nanoparticles was added thiourea as a binder so that a weight ratio of Cu—Zn—Sn—Se nanoparticles to thiourea was set to 3:2. Methanol was added thereto so that the resulting mixture had a solid content of 5% by weight to prepare an ink.

Next, a solar cell was produced in the same process as in Example 1.

Evaluation of the solar cells produced in Examples 1 and 2 were performed using a standard solar radiation simulator (light intensity: 100 mW/cm² and air mass: 1.5). As a result, the photoelectric conversion efficiency was a high value, such as 3.1% or 2.5%. This shows that the CZTS solar cells having excellent properties were obtained at a low cost by the production method which can be easily operated and involves low environmental burden.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A method for producing a nanoparticle for forming a CZTS compound semiconductor thin film, the method comprising:
reacting a solution including a metal salt or a metal complex with a solution including a chalcogenide salt to produce a CZTS compound nanoparticle.

2. The method for producing a nanoparticle for forming a CZTS compound semiconductor thin film according to claim 1, wherein the nanoparticle is produced at a temperature of −67° C. or higher and 25° C. or lower.

3. The method for producing a nanoparticle for forming a CZTS compound semiconductor thin film according to claim 1, wherein the metal salt comprises a halogen atom.

4. The method for producing a nanoparticle for forming a CZTS compound semiconductor thin film according to claim 1, wherein the metal salt is a metal iodide salt.

5. The method for producing a nanoparticle for forming a CZTS compound semiconductor thin film according to claim 4, wherein the metal iodide salt is at least one selected from the group consisting of CuI, ZnI₂, and SnI₂.

6. The method for producing a nanoparticle for forming a CZTS compound semiconductor thin film according claim 1, wherein the chalcogenide salt is at least one selected from the group consisting of Na₂Se and Na₂S.

7. The method for producing a nanoparticle for forming a CZTS compound semiconductor thin film according to claim 1, wherein the nanoparticle comprises a compound represented by Cu₂₋ₓZn_{1+y}SnS_{z}Se_{4-z} (0≦x≦1, 0≦y≦1, 0≦z≦4).

8. The method for producing a nanoparticle for forming a CZTS compound semiconductor thin film according to claim 1, wherein the nanoparticle is at least one selected from the group consisting of a compound represented by Cu₂₋ₓS_{y}Se_{2-y} (0≦x≦1, 0≦y≦2), a compound represented by Zn₂₋ₓS_{y}Se_{2-y} (0≦x≦1, 0≦y≦2), and a compound represented by Sn₂₋ₓS_{y}Se_{2-y} (0≦x≦1, 0≦y≦2).

9. The method for producing a nanoparticle for forming a CZTS compound semiconductor thin film according to claim 1, wherein the nanoparticles have a particle diameter of 1 to 200 nm.

10. The method for producing a nanoparticle for forming a CZTS compound semiconductor thin film according to claim 7, wherein a composition ratio Cu/(Zn+Sn) of elements in the compound forming the nanoparticles is from 0.6 to 0.99.

11. A nanoparticle for forming a CZTS compound semiconductor thin film produced by the method according to claim 1.

12. An ink for forming the CZTS compound semiconductor thin film comprising the nanoparticle according to claim 11 dispersed in an organic solvent.

13. A method for producing an ink for forming the CZTS compound semiconductor thin film, the method comprising:
dispersing the nanoparticle according to claim 11 in an organic solvent selected from the group consisting of methanol and pyridine.

14. The method for producing an ink for forming the CZTS compound semiconductor thin film according to claim 13, further comprising the step of adding at least one selected from the group consisting of a Se compound and a S compound to the ink as a binder.

15. The method for producing an ink for forming the CZTS compound semiconductor thin film according to claim 13, further comprising the step of adding thiourea to the ink as a binder.

16. The method for producing an ink for forming the CZTS compound semiconductor thin film according to claim 13, further comprising the step of adding a particle of at least one selected from the group consisting of a particle including a Se element and a particle including a S element to the ink as a binder.

17. The method for producing an ink for forming the CZTS compound semiconductor thin film according to claim 13, further comprising the step of adding a particle of at least one selected from the group consisting of Se a particle and a S particle to the ink as a binder, the particle having a diameter of 1 to 200 nm.

18. A CZTS compound semiconductor thin film formed by coating or printing the ink for forming the CZTS compound semiconductor thin film according to claim 12, and subjecting it to a heat treatment.

19. A solar cell comprising a light-absorbing layer made of a CZTS compound semiconductor thin film formed by coating or printing the ink for forming the CZTS compound semiconductor thin film according to claim 12 on an electrode formed on a substrate, and subjecting it to a heat treatment.

20. A method for producing a solar cell comprising the steps of:
coating or printing the ink for forming the CZTS compound semiconductor thin film according to claim 12 on an electrode formed on a substrate to form a coating film of a CZTS compound semiconductor; and
subjecting the coating film of the CZTS compound semiconductor to a heat treatment at a temperature of 450° C. to 650° C. to form a light-absorbing layer comprising the CZTS compound semiconductor thin film.
